(19) United States
(12) Patent Application Publication
(10) Pub. No.: US 2024/0176933 A1
(43) Pub. Date: May 30, 2024

(54) DIGITAL TWIN BASED METHOD FOR MONITORING BEHAVIOR OF PASSENGER ON ESCALATOR

(71) Applicant: China Jiliang University, Zhejiang (CN)

(72) Inventors: Gang Xiao, Zhejiang (CN); Jiawei Lu, Zhejiang (CN); Qibing Wang, Zhejiang (CN); Chen Li, Zhejiang (CN); Nan LV, Zhejiang (CN); Jinjin Dong, Zhejiang (CN); Hairui Gu, Zhejiang (CN)

(73) Assignee: China Jiliang University, Zhejiang (CN)

(21) Appl. No.: 18/366,588

(22) Filed: Aug. 7, 2023

(30) Foreign Application Priority Data
Nov. 29, 2022 (CN) 202211508241.8

(51) Int. Cl. G06F 30/27; G06T 17/00; G06T 19/20; G06V 10/764; G06V 10/77; G06V 10/774; G06V 10/776; G06V 10/82; G06V 20/52; G06V 20/64; G06V 40/20

(52) U.S. Cl. CPC G06F 30/27; G06T 17/00; G06T 19/20; G06V 10/764; G06V 10/7715; G06V 10/774; G06V 10/776; G06V 10/82; G06V 20/52; G06V 20/64; G06V 40/23; G06T 2219/2004

(57) ABSTRACT

A digital twin based method for monitoring behavior of a passenger on an escalator includes: first, constructing a digital twin virtual scene of the escalator carrying the passenger; constructing a virtual person model in a physics engine, generating various types of risky behavior in reality, and outputting different types of behavior of a virtual person; second, through a human posture recognition method for monitoring behavior of a passenger, extracting a feature map as an input by means of a visual geometry group 19 (VGG19) pre-training network, to enter part affinity fields (PAFs) and a part confidence map (PCM), so as to complete recognition of human postures; classifying the human postures with a support vector machine; and performing emergency stop control on the escalator under risky behavior of the passenger according to a result of posture classification.

### CROSS-REFERENCE TO RELATED APPLICATION

This application claims the priority benefit of China application serial no. 202211508241.8, filed on Nov. 29, 2022. The entirety of the above-mentioned patent application is hereby incorporated by reference herein and made a part of this specification.

### TECHNICAL FIELD

The present invention belongs to the field of escalator monitoring, and relates to a digital twin based method for monitoring behavior of a passenger on an escalator.

### BACKGROUND

The concept of digital twin was first proposed by University of Michigan professor Michael Grieves in 2017, when it was named “information mirroring model”, and later evolved into “digital twin”. The digital twin refers to a simulation process that makes full use of physical models, sensors, operational history, and other data and integrates multidisciplinary and multi-scale simulation. As a mirror image of a physical product in virtual space, the digital twin reflects a full life-cycle process of the corresponding physical entity product. Nowadays, the digital twin has the conditions to be achieved with the continuous development of the modern sensing technology, the communication technology and the artificial intelligence. In 2019, professor Tao Fei proposed a five-dimensional model including a physical layer, a virtual layer, a connection layer, an information layer and a service layer for achieving the digital twin, and the five-dimensional model is applied in the fields of industrial manufacturing and mechanical apparatus management and maintenance, etc. In recent years, the digital twin theory has been developing and is widely used in smart manufacturing, digital equipment, smart cities and other fields. The digital twin technology integrates numerous cutting-edge technologies, so it can be implemented in specific fields and real engineering projects.

At present, escalator safety monitoring mainly includes two means. One means is to allocate special security personnel to an escalator at an entrance and an exit, to maintain the site order of escalator operation, but manual maintenance will consume huge human resources and cannot immediately stop the operation of the apparatus when a danger occurs. The other means is to detect a human body through infrared, ultrasonic, and other devices, and to play the voice prompts of “please stand firm, hold the handrail, and pay attention to the safety”, which cannot alert and respond to the danger.

### SUMMARY

In order to overcome the defects of the prior art, the present invention provides a digital twin method for monitoring behavior of a passenger on an escalator based on man-machine-information-service, and solves the question of monitoring risky behavior of passengers in practice. The early warning of the potential risky behavior of the passengers is implemented, and automatic operation stop of the escalator apparatus at the first time of falling is implemented. The present invention has the advantages of high real-time, high accuracy and high interactivity, and improves the degree of intelligence and digitization of operation and maintenance of the escalator.

The technical solution used in the present invention to solve the technical problem is as follows:

A digital twin based method for monitoring behavior of a passenger on an escalator includes:
step 1: constructing a digital twin virtual scene where the escalator carries the passenger, where a process specifically includes:
step (1.1) drawing a geometric model of an escalator apparatus and the passenger: drawing the geometric model by means of three-dimensional modeling software, where the geometric model is a basic link of construction of the digital twin scene, and determines a final realization effect of the digital twin scene and a degree of fidelity of the virtual scene;
step (1.2) constructing the scene: constructing the same subject as that in reality for a most complex step system in the geometric model, defining an attribute of a motion component, and defining a data interface of the motion component; and
step (1.3) driving the model;
step 2: constructing a virtual person model in a physics engine, generating a virtual person model generating different actions corresponding to various types of risky behavior in reality, making a virtual camera, and outputting different types of behavior of a virtual person, where a process includes:
step (2.1) obtaining behavior data of an actual person, and performing posture decomposition to obtain 18 key points described in step 1;
step (2.2) designing action simulation behavior of the virtual person, reorienting a skeleton model of the virtual person in the physics engine, that is, achieving simulation of the actual person by means of rotation and displacement in the skeleton model, matching a relation between skeleton points anew by means of matching set, and editing a space position of each key point of the virtual person, to simulate the behavior of the passenger in a real world; and
step (2.3) adding the virtual camera in the physics engine, binding visual angle selection of the camera with the virtual person, setting a photographing parameter of the virtual camera, selecting an output save path, and using a video image of the virtual person as input of behavior posture recognition and classification;
step 3, using a visual geometry group 19 (VGG19) pre-training network by a human posture recognition method for monitoring behavior of a passenger, extracting a feature map as input, to enters two branches of part point affinity fields (PAFs) and point confidence maps (PCM), and using the PAFs to express a trend of a pixel point on a posture, where a process includes:
step (3.1) obtaining the feature map from an original image by means of the VGG19;
step (3.2) outputting the obtained feature map to a next layer, to enter the two branches of PAFs and PCM, and outputting one Loss in each stage;
step (3.3) generating and computing a confidence map of S by using an image of two-dimensional key points, where S*_{j,k}(p) represents all confidence maps generated by k persons, X_{j,k} represents a jth key point of a kth person in the image, and a maximum value of S*_{j,k}(p) is used to represent a finally obtained confidence map of key point parts of a plurality of persons; and a predicted value at p is:

$${S}_{j , k}^{*} ( p ) = exp ( - \frac{{‖ p - {X}_{j , k} ‖}_{2}^{2}}{{δ}^{2}} )$$

where exp is a natural constant e, δ is a diffusion of a control peak, and ∥p−X_{j,k}∥₂² is a square of a vector modulus value from the point p to a position j of the kth person;
step (3.4) defining that X_{i,k} and X_{j,k} represent two key points, and the pixel point p is on a limb, such that a value of L*_{c,k}(p) is a unit vector from i to j of the kth person, where a vector field of the point p is:

$${L}_{c , k}^{*} ( p ) = \{ \begin{matrix}\frac{( {X}_{j , k} - {X}_{i , k} )}{{‖ {X}_{j , k} - {X}_{i , k} ‖}_{2}} , p ∈ {L}_{c , k}^{*} ( p ) \\ 0 , others\end{matrix}$$

where ∥X_{j,k}−X_{i,k}∥₂ is a limb length from a position j to position i of the kth person;
step (3.5) finally obtaining an average affinity field of all the persons as:

$${L}_{c}^{*} ( p ) = \frac{1}{{n}_{c} ( p )} {L}_{c , k}^{*} ( p )$$

where n_{c}(p) represents the number of non-zero vectors at p in all the persons;
step (3.6) in a multi-person scene, computing a score of a limb by means of the following formula, and searching for a situation with a maximum association confidence coefficient;

$$E = {\int }_{u = 0}^{u = 1} {L}_{c} ( p ( u ) ) \frac{{d}_{j 2} - {d}_{j 1}}{‖ {d}_{j 2} - {d}_{j 1} ‖} du$$

where E is the association confidence coefficient, ∥dⱼ₂−dⱼ₁∥₂ is a distance between body parts dⱼ₂,dⱼ₁, and p(u) interpolates positions of the body parts dⱼ₂, dⱼ₁:

p(u)=(1−u)dⱼ₁+dⱼ₂

where an integral value is approximated by means of sampling and equally spaced sums over u; and
step (3.7) changing a multi-person measurement question into a bipartite graph matching question, to obtain an optimal solution of connected points, obtaining all limb prediction results, and connecting all key points of a human body; where
bipartite graph matching is a subset of edges selected in such a way that two edges share no node, and a goal is to find a matched maximum weight for a selected edge;
step 4, performing posture classification based on a support vector machine (SVM), using 1-V-1(one-versus-one) to classify human postures since the plurality of human postures need to be classified, and designing one SVM classifier for every two classes, such that k(k−1)/2 classifiers are needed in total; and
step 5: performing emergency stop control on the escalator under risky behavior.

Further, in step (1.1), the escalator has eight systems of a truss, a step system, a handrail belt system, a guide rail system, a handrail device, a safety protection device, an electrical control system, and a lubrication system;
the truss is a support structure of the escalator, and is configured to mount and support various components of the escalator;
the step system is a working part of the escalator, and is composed of step treads, a
drive main machine, a step chain, a main drive shaft and a roller chain, where
the handrail belt system functions to provide a set of handrail belts synchronized with steps in movement, so as to achieve synchronization of a hand and a body when the passenger takes the elevator;
the guide rail system is configured to support a load transmitted by a main wheel and
an auxiliary wheel of the steps, to prevent the steps from running away;
the handrail device is also called a guardrail or an armrest, and is arranged on two sides of the escalator;
the safety protection device is various protection devices set on the escalator for a potential safety hazard;
the electrical control system is to implement drive control over an electric motor, and to perform safety monitoring and safety protection on operation of the escalator;
the lubrication system is configured to lubricate machine parts of the escalator, reasonable lubrication reduces wear of moving components and prolongs the service life of the escalator; and
a human model is simplified to a virtual skeleton model with 18 key points having limited rotation displacement, where
the 18 key points are respectively 1 nose, 2 left eye, 3 right eye, 4 left ear, 5 right ear, 6 left shoulder, 7 right shoulder, 8 left elbow, 9 right elbow, 10 left wrist, 11 right wrist, 12 left hip bone, 13 right hip bone, 14 left knee, 15 right knee, 16 left ankle, and 17 right ankle, in human posture recognition, the middle of the left shoulder and the right shoulder is typically taken as a key point of 0 neck, and there are 18 key points in total.

Further, in step (1.2), a movement mode of the step treads in the step system is that any tread is taken as an initial tread, a movement path of the step treads of the escalator is constructed, a movement speed v of the treads is computed from a height and an elevator length, that is, an included angle θ, a constraint is set, the initial tread moves along the path, a movement path length l and an occupation width d of the initial tread in the path are computed, then the number of the step treads is determined as l÷d=n , n is an integer, in response to determining that n is not an integer, the movement path length l or a step tread width is finely adjusted, the initial tread is taken as a parent node, a second tread is bound to the previous tread, a third tread is bound to the second tread, and so on, all the treads form a complete step tread along the movement path, and by controlling a speed of the initial tread, all the treads move along the movement path at the same speed;
movement of the roller chain in the step system is the same as that of the step treads;
the attribute of the motion component is operability of translation and rotation of the motion component in the physics engine; and
the data interface of the motion component is that in the physics engine, start, stop and a speed of a movable component are controlled according to truthful data.

Further, in step (1.3), a process of driving the model includes:
step (1.3.1) uploading operation data of the escalator from a control panel to a client by means of a communication bus, where the client is a digital twin monitoring platform, and establishing bidirectional communication by means of Socket (bidirectional communication between application processes on different hosts in a network);
step (1.3.2) after human posture information is detected from collected passenger behavior data by a video analysis server in step 3, transmitting a passenger behavior video and key point data of the human postures to the client; and
step (1.3.3) receiving warning and stop commands from the client by a Socket server, and sending a command by means of a computer, to control the escalator to stop operating.

In step (3.1), the VGG19 is a convolutional neural network for object recognition, and each layer of the neural network will further extract more complex features by using output of the previous layer until the feature is too complex to be used to recognize an object, such that each layer is regarded as an extractor of many local features, and a process includes:
step (3.1.1) defining that a VGG19 module includes 16 convolutional layers and 3 fully-connected layers, and an input image is 224*224*3 (image pixel size), activating the input image with a rectified linear unit (ReLU) after 64 convolution kernels of 3*3, such that the input image becomes 224*224*64, and performing MAX pooling, such that a pooling window is 2*2, a step size is 2, and a pooled image is 112*112*64; where
each convolutional layer in the convolutional neural network consists of several convolutional units, parameters of each convolutional unit are optimized by a backpropagation algorithm, a purpose of convolutional operation is to extract different input features, the first convolutional layer extracts some low-level feature of edges, lines and corner levels, and more layers of networks iteratively extract more complex features from the low-level features;
in the fully-connected layer, each node is connected to all nodes in the previous layer, to synthesize the features extracted above, and because of a fully connected feature of the fully-connected layer, the fully-connected layer has the most parameters;
during image processing, an input image is provided, pixels in a small region of the input image are weight and averaged to become each corresponding pixel in the output image, a weight is defined by a function, and the function is called the convolution kernel;
the rectified linear unit (ReLU) is a function operating on a neuron of an artificial neural network, and is responsible for mapping input of the neuron to an output end and used for output of a hidden layer neuron;
MAX pooling is to take a point with a maximum value from a local acceptance domain, and a size of a MAX pooling convolution kernel is 2*2;
step (3.1.2) performing 128 convolutions of 3*3 and the ReLU, such that the feature becomes 112*112*128, and performing 2*2 MAX pooling, such that a size becomes 56*56*128;
step (3.1.3) performing 256 convolutions of 3*3 and the ReLU, such that the feature becomes 56*56*256, and performing 2*2 MAX pooling, such that the feature size becomes 28*28*256;
step (3.1.4) performing 512 convolutions of 3*3 and the ReLU, such that the feature becomes 28*28*512, and performing 2*2 MAX pooling, such that the feature size becomes 14*14*512;
step (3.1.5) performing 512 convolutions of 3*3 and the ReLU, such that the feature becomes 14*14*512, and performing 2*2 MAX pooling, such that the feature size becomes 7*7*512; and
step (3.1.6) by means of two layers of 1*1*4096 and one layer of 1*1*1000 of the

fully-connected layers and the ReLU, finally outputting 1000 prediction results by means of Softmax, where
a Softmax normalized exponential function is an extension of a logic function, and compresses a U-dimensional vector z containing any real number into another U-dimensional real vector a(z), such that a range of each element is between (0,1), and a sum of all elements is 1.

A process of step (3.2) includes:
step (3.2.1) defining an iteration formula of the branch PAFs as follows:

S^{t}=ρ^{t}(F, L^{t-1}, S^{t-1}), t≥2

where ρ^{t} represents an iterative relation of a stage t, F is the feature map, L represents the part affinity field, S represents the two-dimensional confidence map, and t represents the total number of stages;
step (3.2.2) defining an iteration formula of the branch PCM as follows:

L^{t}=ϕ^{t}(F, L^{t-1}, S^{t-1}), t≥2

where ϕ^{t} represents the iterative relation of the stage t;
step (3.2.3) defining a loss function of the branch PAFs as follows:

$${f}_{S}^{t} = {\sum }_{j = 1}^{J} {\sum }_{P} W ( p ) {‖ {S}_{j}^{t} ( p ) - {S}_{j}^{*} ( p ) ‖}_{2}^{2}$$

where fₛ^{t} is the loss function of the branch PAFs, S*ⱼ(p) is a confidence map of a real key point position, W is a binary code, and when no mark is made at the image pixel position p, W(p) is 0, otherwise is 1; and ∥Sⱼ^{t}(p)−S*ⱼ(p)∥₂² is a square of a difference between a predicted value and a true value; and
step (3.2.4) defining a loss function of the branch PCM as follows:

$${f}_{L}^{t} = {\sum }_{c = 1}^{C} {\sum }_{P} W ( p ) {‖ {L}_{c}^{t} ( p ) - {L}_{c}^{*} ( p ) ‖}_{2}^{2}$$

where f_{L}^{t} is the loss function of the branch PAFs, L*_{c}(p) is a part affinity field of real key points, and ∥L_{c}^{t}(p)−L*_{c}(p)∥₂² is the square of the difference between the predicted value and the true value.

A process of step 4 includes: step (4.1) performing data processing and normalization: training and testing data, to select a posture key point coordinate, and normalizing key point coordinate data in different types of posture data, where
normalization processing is to scale the key point coordinate data to [−1, 1];
step (4.2) selecting a radial basis function kernel as a kernel function, where definition of the radial basis kernel function is as follows:

$$K ( x , {x}^{′} ) = exp ( - \frac{{‖ x - {x}^{′} ‖}_{2}^{2}}{2 {σ}^{2}} )$$

where x and x′ are two trained samples, ∥x−x′∥₂² is a squared Euclidean distance between vectors, and σ is a free parameter;
step (4.3) selecting reasonable training parameters c and g, where c represents an importance degree of the model to discrete group data, and g is γ=½σ² in the kernel function;
step (4.4) using the parameters of step (4.3) to train a posture classification model; and
step (4.5) verifying accuracy of classification, and verifying an accuracy rate of classification of a test set according to the trained model.

A process of step 5 includes:
step (5.1) after the human posture information is detected by the video analysis server, transmitting the passenger behavior video and the key point data of the human postures to the client;
step (5.2) classifying results of passenger behavior recognition by the client, to correspondingly trigger a state machine in the virtual scene, where a posture recognition result triggers the virtual person behavior to be converted into a corresponding posture, where
the state machine is a tool in the physics engine that makes one action of the virtual person transition to another action; and
step (5.3) sending out the warning and stop commands by the client according to the result of classification of passenger recognition, and sending the commands to a control mainboard of the elevator by means of the communication bus, to control the escalator to stop operating.

A technical idea of the present invention including: first, constructing a digital twin virtual scene where the escalator carries the passenger; constructing a virtual person model in a physics engine, generating various types of risky behavior in correspondence to reality, and outputting different types of behavior of a virtual person; second, through a human posture recognition method for monitoring behavior of a passenger, extracting a feature map as an input by means of a VGG19 pre-training network, to enter part affinity fields (PAFs) and a part confidence map (PCM), so as to complete recognition of human postures; classifying the human postures with a support vector machine; and performing emergency stop control on the escalator under risky behavior of the passenger according to a result of posture classification, and finally designing a visual digital twin interface of passenger behavior monitoring.

The present invention has the beneficial effects that a man-machine-information-service digital twin virtual scene where an escalator carries passengers is constructed, and a digital twin virtual person is used to simulate risky behavior, to make up for a lack of data and solve a question of passenger risky behavior monitoring in practice. A three-dimensional visual interface of digital twin vividly and intuitively displays an operation state of the escalator apparatus and behavior information of the passengers, so as to implement early warning of potential risky behavior of the passengers, and implement automatic operation stop of the escalator apparatus at the first time of falling. The digital twin based method for monitoring behavior of a passenger on an escalator has the advantages of high real-time, high accuracy and high interactivity, and improves the degree of intelligence and digitization of operation and maintenance of the escalator.

### BRIEF DESCRIPTION OF THE DRAWINGS

FIG. 1 shows a geometric model of an escalator and a passenger in a digital twin.

FIG. 2 is a schematic diagram of driving a model in a digital twin.

FIG. 3 shows an effect of digital twin virtual bionics of a human posture.

FIG. 4 is a structural diagram of a human posture recognition network.

FIG. 5 shows a visual interface design of a digital twin method for monitoring behavior of a passenger.

### DETAILED DESCRIPTION OF THE EMBODIMENTS

The present invention will be further described hereafter in conjunction with the accompanying drawings.

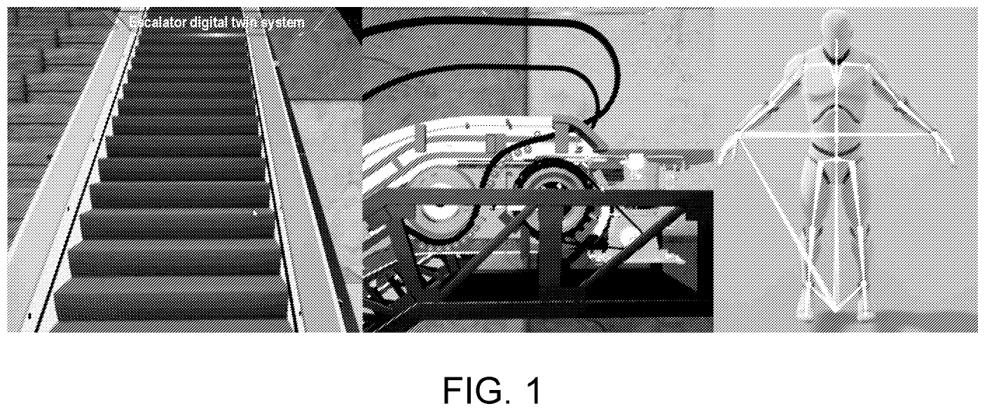

With reference to FIGS. 1-4, a digital twin based method for monitoring behavior of a passenger on an escalator includes:

Step 1, the present invention provides construction of a digital twin virtual scene for monitoring behavior of the passenger on the escalator, where an implementation framework of a digital twin system for monitoring behavior of a passenger on an escalator is divided into four layers of a physical layer, an information layer, a virtual layer and a management execution layer.

FIG. 1 is a geometric model of the escalator and the passenger in a digital twin.

Step (1.1) establishment of the geometric model is a basic link of construction of the digital twin scene, which determines a final realization effect of the digital twin scene and a degree of fidelity of achievement of the digital twin. According to scene object, two objects of man-machine may be provided. As for the escalator, the escalator has eight systems of a truss, a step system, a handrail belt system, a guide rail system, a handrail device, a safety protection device, an electrical control system, and a lubrication system. According to human behavior in a real world, a human model is simplified into a skeleton model, and the skeleton model is connected by 18 key points.

The 18 key points are respectively 1 nose, 2 left eye, 3 right eye, 4 left ear, 5 right ear, 6 left shoulder, 7 right shoulder, 8 left elbow, 9 right elbow, 10 left wrist, 11 right wrist, 12 left hip bone, 13 right hip bone, 14 left knee, 15 right knee, 16 left ankle, and 17 right ankle, in human posture recognition, the middle of the left shoulder and the right shoulder is typically taken as a key point of 0 neck, and there are 18 key points in total.

Step (1.2) the same subject as that in reality is constructed for a most complex step system in the geometric model, an attribute of a motion component is defined, and a data interface of the motion component is defined.

The attribute of the motion component is operability of translation and rotation of the motion component in an unreal engine (UE).

The data interface of the motion component is that in the UE, start, stop and a speed of a movable component are controlled according to truthful data.

The unreal engine (UE) is a real-time interactive rendering engine used in game development, architecture, virtual reality (VR) and other fields.

Step (1.2.1), a movement mode of the step treads in the step system is that any tread is taken as an initial tread, a movement path of the step treads of the escalator is constructed, a movement speed v of the treads is computed from a height and an elevator length, that is, an included angle θ, a constraint is set, the initial tread moves along the path, a movement path length l and an occupation width d of the initial tread in the path are computed, then the number of the step treads is determined as l÷d=n, n is an integer, in response to determining that n is not an integer, the movement path length l or a step tread width is finely adjusted, the initial tread is taken as a parent node, a second tread is bound to the previous tread, a third tread is bound to the second tread, and so on, all the treads form a complete step tread along the movement path, and by controlling a speed of the initial tread, all the treads move along the movement path at the same speed.

Step (1.2.2) movement of the roll chain is constructed same as that of step treads, a data interface is defined, and transmission data is analyzed.

Step (1.2.3) a speed of a drive motor is selected, the escalator generally uses a 4-stage motor or a 6-stage motor, a synchronous speed of the 4-stage motor is generally set to be 1500 r/min, a size is smaller, the efficiency is higher, and the motor selection in the present invention corresponds to an actual 4-stage motor, such that a speed is set to be 1500 r/min.

Step (1.2.4) a rotation speed of a drive wheel of a handrail belt is defined, theoretically, a speed of the handrail belt should be equal to a speed of the step treads, so as to avoid the passenger falling down caused by asynchronous operation speeds of the handrail belt and the treads, however, according to the national standard, the speed of the handrail belt can be 0-2% higher than the speed of the step treads, and the speed of the handrail belt is slightly higher, such that a center of gravity of a person is in front, and a hand position can be slightly adjusted.

Step (1.2.5) a step roll speed is defined, the step roller speed is excited by the step treads, to follow the movement of the step treads.

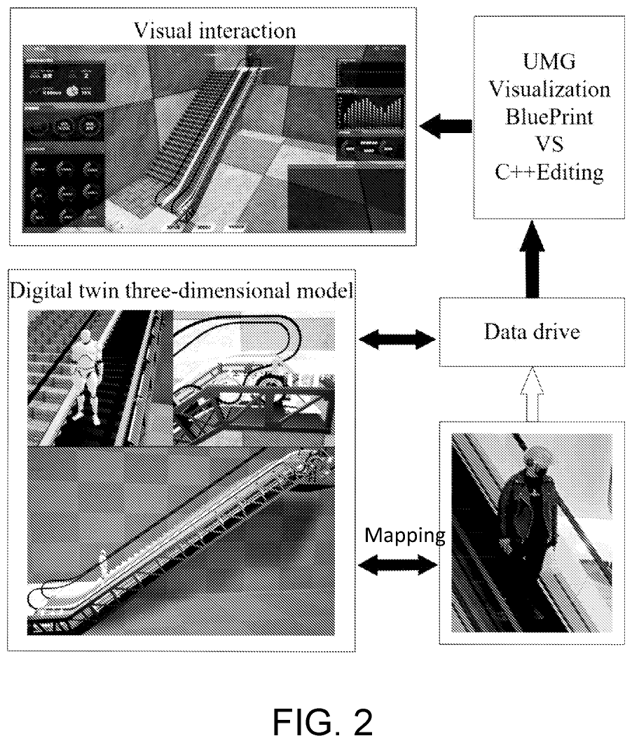

Step (1.3) the model is driven. FIG. 2 is a schematic diagram of driving the model.

A map is synchronization of the virtual and the real in the digital twin.

Data drive is used for model drive.

Unreal motion graphics (UMG) visualization is a resource component used in the UE to create and display an interface.

BluePrint is a visual scripting language in the UE for object-oriented programming.

VS C++ editing is to use C++ programming to customize a development scene in conjunction with Visual Studio 2019 in the UE.

Step (1.3.1) operation data of the escalator is uploaded from a control panel to a client by means of a RS485 (a communication protocol commonly used in an industrial apparatus) bus, where the client is a digital twin monitoring platform, and bidirectional communication is established by means of Socket (bidirectional communication between application processes on different hosts in a network).

The digital twin client may be similarly configured as follows: Windows10 operating system, processor i7 10750H, memory 64GB DDR4, graphics card NVIDIA RTX3060, and Unreal Engine 4.26.

Step (1.3.2) after human posture information is detected from collected passenger behavior data by a video analysis server in step 3, a passenger behavior video and key point data of the human postures are transmitted to the client.

Step (1.3.3) a Socket server receives warning and stop commands from the client, and sends a command by means of a computer, to control the escalator to stop operating.

Step 2: a virtual person model is constructed in the UE, a virtual person model generating different actions corresponding to various types of risky behavior in reality is generated, a virtual camera is made, and different types of behavior of a virtual person are output.

Step (2.1) behavior data of an actual person is obtained, and posture decomposition is performed to obtain 18 key points being 1 nose, 2 left eye, 3 right eye, 4 left ear, 5 right ear, 6 left shoulder, 7 right shoulder, 8 left elbow, 9 right elbow, 10 left wrist, 11 right wrist, 12 left hip bone, 13 right hip bone, 14 left knee, 15 right knee, 16 left ankle, and 17 right ankle, in human posture recognition, the middle of the left shoulder and the right shoulder is typically taken as a key point of 0 neck, and there are 18 key points in total.

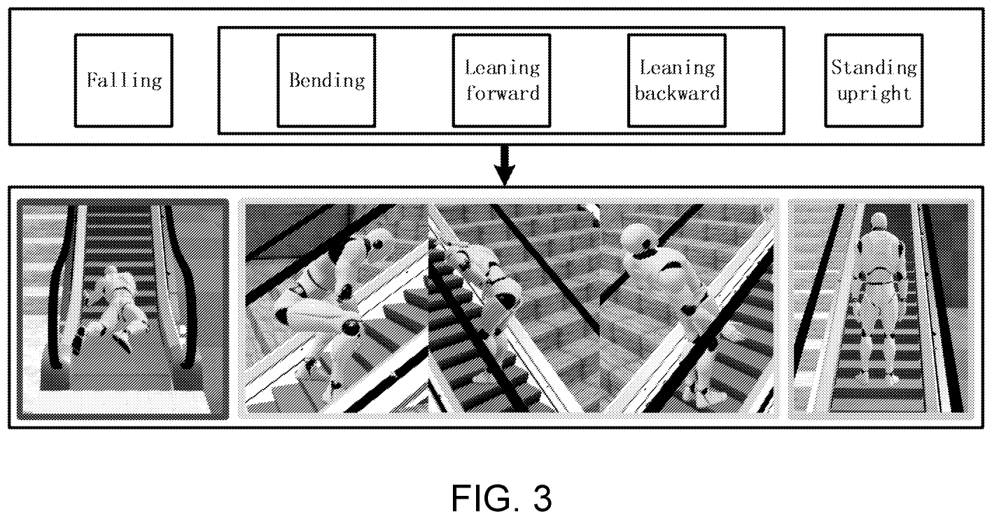

Step (2.2) as shown in FIG. 3, action simulation behavior of the virtual person is designed, a skeleton model of the virtual person is reoriented in the UE, that is, simulation of the actual person by means of rotation and displacement in the skeleton model is achieved, a relation between skeleton points is matched anew by means of matching set, a space position of each key point of the virtual person is edited, a layer track is added, a curve frame by frame is edited, and axial setting is edited, to implement driving of the action behavior of the virtual person.

In FIG. 3, the human postures are divided into five types of falling, bending, leaning forward, leaning backward and standing upright. Falling is a danger level, bending, leaning forward and leaning backward are early warning levels, and standing upright is a safe level.

Step (2.3) a camera is added in the UE, an angle of view of the camera is bound to the virtual person, a camera photographing parameter of the virtual person is set, a MP4 format of a resolution of 30 frames and 1280*720P is set, and an output save path is selected. A video image of the virtual person is used for input of behavior posture recognition and classification.

Step 3, a human posture recognition method for monitoring behavior of a passenger uses a visual geometry group 19 (VGG19) pre-training network, a feature map is extracted as input, to enters two branches of part affinity fields (PAFs) and point confidence maps (PCM), and the PAFs are used to express a trend of a pixel point on a posture.

The feature map is a result of convolution of an input image by a neural network, and represents a feature in a neural space. Its resolution depends on a step size of a previous convolution kernel.

Step (3.1) the feature map is obtained from an original image by means of the VGG19.

The VGG19 is a convolutional neural network for object recognition, and each layer of the neural network will further extract more complex features by using output of the previous layer until the feature is complex enough to be used to recognize an object, such that each layer is regarded as an extractor of many local features.

Step (3.1.1) a VGG19 module includes 16 convolutional layers and 3 fully-connected layers, an input image is 224*224*3 (image pixel size), the input image is activated with a rectified linear unit (ReLU) after 64 convolution kernels of 3*3, such that the input image becomes 224*224*64, and MAX pooling is performed, such that a pooling window is 2*2, a step size is 2, and a pooled image is 112*112*64.

Each convolutional layer in the convolutional neural network consists of several convolutional units, parameters of each convolutional unit are optimized by a backpropagation algorithm. A purpose of convolutional operation is to extract different input features, the first convolutional layer extracts some low-level feature of edges, lines and corner levels, and more layers of networks iteratively extract more complex features from the low-level features.

In the fully-connected layer, each node is connected to all nodes in the previous layer, to synthesize the features extracted above. Because of a fully connected feature of the fully-connected layer, the fully-connected layer has the most parameters.

During image processing, an input image is provided, pixels in a small region of the input image are weight and averaged to become each corresponding pixel in the output image, a weight is defined by a function, and the function is called the convolution kernel.

The rectified linear unit (ReLU) is a function operating on a neuron of an artificial neural network, and is responsible for mapping input of the neuron to an output end and used for output of a hidden layer neuron.

MAX pooling is to take a point with a maximum value from a local acceptance domain, and A size of a MAX pooling convolution kernel is 2*2.

Step (3.1.2) 128 convolutions of 3*3 and the ReLU are performed, such that the feature becomes 112*112*128, and 2*2 MAX pooling is performed, such that a size becomes 56*56*128.

Step (3.1.3) 256 convolutions of 3*3 and the ReLU are performed, such that the feature becomes 56*56*256, and 2*2 MAX pooling is performed, such that the feature size becomes 28*28*256.

Step (3.1.4) 512 convolutions of 3*3 and the ReLU are performed, such that the feature becomes 28*28*512, and 2*2 MAX pooling is performed, such that the feature size becomes 14*14*512.

Step (3.1.5) 512 convolutions of 3*3 and the ReLU are performed, such that the feature becomes 14*14*512, and 2*2 MAX pooling is performed, such that the feature size becomes 7*7*512.

Step (3.1.6) by means of two layers of 1*1*4096 and one layer of 1*1*1000 of the fully-connected layers and the ReLU, 1000 prediction results by means of Softmax are finally output.

A Softmax normalized exponential function is an extension of a logic function, and compresses a U-dimensional vector z containing any real number into another U-dimensional real vector α(z), such that a range of each element is between (0,1), and a sum of all elements is 1.

Step (3.2) the obtained feature map is output to a next layer, to enter the two branches

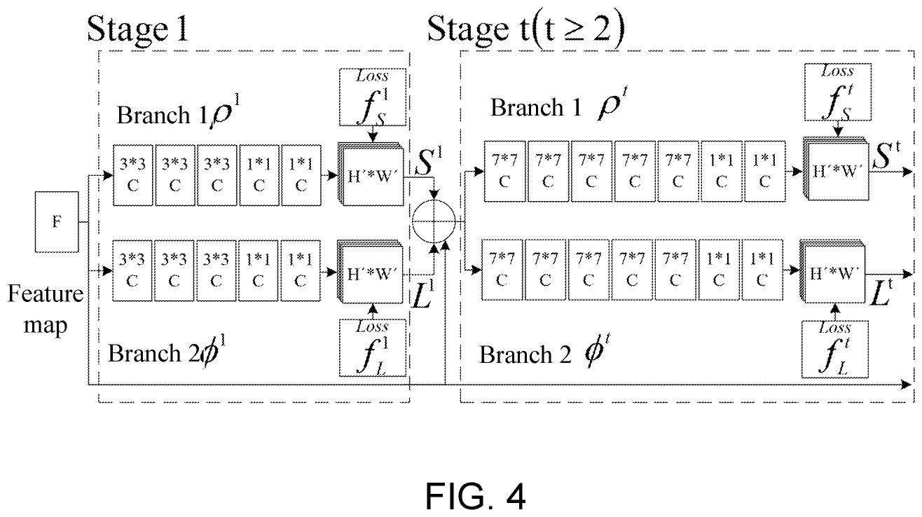

of the part affinity fields (PAFs) and the point confidence maps (PCM), and one Loss function is output in each stage, as shown in FIG. 4.

Stage 1 is a relation between branch 1 (PAFs) and branch 2 (PCM) in a network in a stage 1.

H′*W′ is a feature map extracted by a plurality of layers of convolutions C.

Step (3.2.1) an iteration formula of the branch PAFs is as follows:

S^{t}=ρ^{t}(F, L^{t+1}, S^{t-1}), t≥2

where ρ^{t} represents an iterative relation of a stage t (corresponding to Stage t in FIG. 4), F is the feature map, L represents the part affinity field (corresponding to branch 1), S represents the two-dimensional confidence map (corresponding to branch 2), and t represents the total number of stages.

Step (3.2.2) an iteration formula of the branch PCM is as follows:

L^{t}=ϕ^{t}(F, L^{t-1}, S^{t-1}), t≥2

where ϕ^{t} represents the iterative relation of the stage t (corresponding to Stage t in FIG. 4).

Step (3.2.3) a loss function of the branch PAFs is as follows:

$${f}_{S}^{t} = {\sum }_{j = 1}^{J} {\sum }_{P} W ( p ) {‖ {S}_{j}^{t} ( p ) - {S}_{j}^{*} ( p ) ‖}_{2}^{2}$$

where fₛ^{t} is the loss function of the branch PAFs, S*ⱼ(P) is a confidence map of a real key point position, W is a binary code, and when no mark is made at the image pixel position p, W(p) is 0, otherwise is 1; and ∥Sⱼ^{t}(p)−S*ⱼ(p)∥₂² is a square of a difference between a predicted value and a true value.

Step (3.2.4) a loss function of the branch PCM is as follows:

$${f}_{L}^{t} = {\sum }_{c = 1}^{C} {\sum }_{P} W ( p ) {‖ {L}_{c}^{t} ( p ) - {L}_{c}^{*} ( p ) ‖}_{2}^{2}$$

where f_{L}^{t} is the loss function of the branch PAFs, L*_{c}(P) is a part affinity field of real key points, and ∥L_{c}^{t}(p)−L*_{c}(p)∥₂² is the square of the difference between the predicted value and the true value.

Step (3.3) a confidence map of S is generated and computed by using an image of two-dimensional key points, where S*_{j,k}(p) represents all confidence maps generated by k persons, X_{j,k} represents a jth key point of a kth person in the image. A maximum value of S*_{j,k}(p) is used to represent a finally obtained confidence map of key point parts of a plurality of persons. A predicted value at p is:

$${S}_{j , k}^{*} ( p ) = exp ( - \frac{{‖ p - {X}_{j , k} ‖}_{2}^{2}}{{δ}^{2}} )$$

where exp is a natural constant e, δ is a diffusion of a control peak, and ∥p−X_{j,k}∥₂² is a square of a vector modulus value from the point p to a position j of the kth person.

Step (3.4) X_{i,k} and X_{j,k} represent two key points, and the pixel point p is on a limb, such that a value of L*_{c,k}(p) is a unit vector from i to j of the kth person, where a vector field of the point p is:

$${L}_{c , k}^{*} ( p ) = \{ \begin{matrix}\frac{( {X}_{j , k} - {X}_{i , k} )}{{‖ {X}_{j , k} - {X}_{i , k} ‖}_{2}} , & p ∈ {L}_{c , k}^{*} ( p ) \\ 0 , & others\end{matrix}$$

where ∥X_{j,k}−X_{i,k}∥₂ is a limb length from a position j to position i of the kth person.

Step (3.5) an average affinity field of all the persons is finally obtained as:

$${L}_{c}^{*} ( p ) = \frac{1}{{n}_{c} ( p )} {L}_{c , k}^{*} ( p )$$

where n_{c}(p) represents the number of non-zero vectors at p in all the persons.

Step (3.6) in a multi-person scene, a score of a limb is computed by means of the following formula, and a situation with a maximum association confidence coefficient is searched.

$$E = {\int }_{u = 0}^{u = 1} {L}_{c} ( p ( u ) ) \frac{{d}_{j 2} - {d}_{j 1}}{‖ {d}_{j 2} - {d}_{j 1} {‖}_{2}} du$$

where E is the association confidence coefficient, ∥dⱼ₂−dⱼ₁∥₂ is a distance between body parts dⱼ₂, dⱼ₁, and p(u) interpolates positions of the body parts dⱼ₂, dⱼ₁:

p(u)=(1−u)dⱼ₁+dⱼ₂

where an integral value is approximated by means of sampling and equally spaced sums over u; and

Step (3.7) a multi-person measurement question is changed into a bipartite graph matching question, to obtain an optimal solution of connected points, all limb prediction results are obtained finally, and all key points of a human body are connected.

Bipartite graph matching is a subset of edges selected in such a way that two edges share no node, and a goal is to find a matched maximum weight for a selected edge.

Step (3.8) a common objects in context 2017 (COCO2017) data set is used for training human posture recognition, 64115 images of a Person_keypoints data part of human posture data in the data set are selected, the trained and tested data are distributed in a ratio of 4:1, and a data format is a JSON file form.

Step (3.9) the video analysis server can be configured as follows: Ubuntu 20.04 operating system, TensorFlow 1.15.4, processor 12700H, memory 32GB DDR4, graphics card NVIDIA RTX3080, and solid-state disk 1TB.

Step 4: a one-versus-one support vector machine (1-v-1SVM) method provided by a libsvm library in Python is used to train 10 classifiers, to get a final classification result. Compared with a classification method of key point inclination computation, the SVM classifier has lower requirements on the data set, and SVM classification can automatically deal with a situation that some key points are missing due to occlusion.

Step (4.1) data processing and normalization is performed: data are trained and tested to select a posture key point coordinate, in the posture data, there are 18 key point coordinate data, and the key point coordinate data in the data of five classified postures of standing, leaning forward, leaning backward, bending and falling are normalized.

Normalization processing is to scale the key point coordinate data to [−1, 1].

Step (4.2) a radial basis function (RBF) kernel is selected as a kernel function, where definition of the radial basis kernel function is as follows:

$$K ( x , {x}^{′} ) = exp ( - \frac{{‖ x - {x}^{′} ‖}_{2}^{2}}{2 {σ}^{2}} )$$

where x and x′ are two trained samples, ∥x−x′∥₂² is a squared Euclidean distance between vectors, and σ is a free parameter.

Step (4.3) reasonable training parameters c and g are selected, where c is a penalty factor and represents an importance degree of the model to discrete group data, the smaller the c is, the smaller an influence of the outlier on the loss function is, and g is γ=½σ² in the kernel function.

Step (4.4) the parameters selected in step (4.3) and a svmtrain function provided in the libsvm library are used to train a posture classification model.

Step (4.5) accuracy of classification is verified, and an accuracy rate of classification of a test set is verified according to the trained model by using a svmpredict function provided in the libsvm library.

Step 5: emergency stop control on the escalator under risky behavior is performed.

Step (5.1) after the human posture information is detected by the video analysis server, the passenger behavior video and the key point data of the human postures are transmitted to the client.

Step (5.2) the client classifies results of passenger recognition, to correspondingly trigger a state machine in the virtual scene, where a posture recognition result triggers the virtual person behavior to be converted into a corresponding posture.

The state machine is a tool in the physics engine that makes one action of the virtual person transition to another action.

Step (5.3) the client sends out the warning and stop commands according to the result

of classification of passenger recognition, and sends the commands to a control mainboard of the elevator by means of the communication bus, to control the escalator to stop operating.

Step (5.4) a video image collection device may has a specific specification of 8 million pixel 1/2.5, power supply DC5V 500 mA, maximum support of 2592*1944-30 frames, USB3.0 interface, and working temperature of −20° C.-70° C. Resolution of video data herein has 1280*720−30 frames, 24 bits true color, and a transmission rate of 79.1 MB/s.

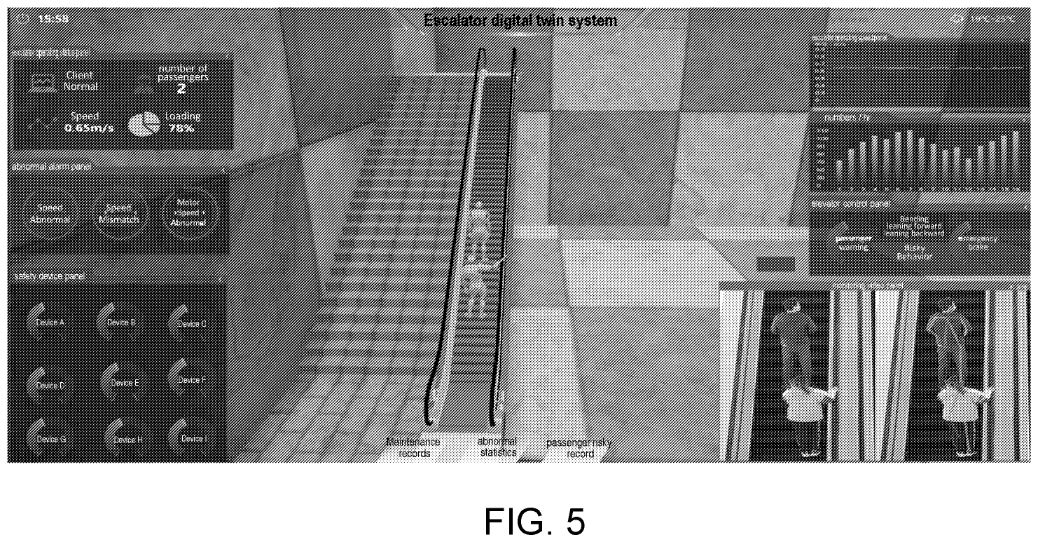

With reference to FIG. 5, a visual interface design method for a digital twin based method for monitoring behavior of a passenger on an escalator includes:

Step 1: a visual interface design mode for a digital twin based method for monitoring behavior of a passenger on an escalator is as follows.

Step (1.1) as shown in FIG. 5 of a visual interface, an unreal motion graphics UI designer (UMG) of the UE is used for visual interface design, and visual chart information is distributed on two sides of a virtual scene, to enhance man-machine interaction experience.

Step (1.2) real-time transmission of data is analyzed by means of transmission control protocol (TCP) socket connection (the unreal engine (UE) integrates a TCP Socket communication module), which is convenient for management by operation and maintenance personnel at the client.

Step 2: display on a left side of the visual design in an escalator digital twin is as follows.

Step (2.1) a first panel on the left side displays normal and abnormal postures of pedestrians, the number of passengers, a speed of the escalator and a load of the elevator.

Step (2.2) a second panel is an abnormal alarm panel, which mainly displays three buttons of elevator speed, mismatch between handrail speed and step speed, and abnormal motor speed, and a red alarm will appear on the panel in case of abnormality.

Step (2.3) a third panel is a safety device panel, monitors whether output state information of a safety protection device mounted on the escalator is abnormal, and includes an additional brake, a working brake, drive chain detection, a step chain, a comb plate, a handrail belt entrance, step sinking, step missing and a braking state. In response to determining that an abnormal signal instruction output by an elevator control system is detected, the corresponding display panel will display the red alarm.

Step 3: display on a right side of the visual design in the escalator digital twin is as follows.

Step (3.1) a first display panel on the right side is an escalator operating speed panel to display a real-time operating speed of the elevator.

Step (3.2) a second display panel on the right side displays a histogram statistical information table of the number of people carried by the escalator per hour.

Step (3.3) a third display panel on the right side is an elevator control panel for a passenger behavior recognition result, a passenger warning button is triggered for risky behavior, and an elevator emergency brake button is trigger for falling behavior of the passenger.

Step (3.4) a last display panel on the right side is a passenger behavior monitoring video panel, and displays a behavior posture of the passenger on the escalator in real time.

Step 4, display on a body of the visual design in the escalator digital twin is as follows.

Step (4.1) the middle of the display interface is a digital twin, which is divide into an escalator apparatus and an individual passenger accord to objects, a virtual escalator model is driven according to real-time data, step treads, a drive wheel, a handrail belt drive wheel and a drive motor in the model are driven by the real-time data, a drive mode is to determine data reception and analyze a speed, and the model moves around a y axis in a digital virtual space.

Step (4.2) the behavior of the passenger is mapped to a virtual person in a digital twin space according to the result of human posture recognition, the corresponding number of virtual persons is generated according to the number of detected passengers, and the virtual persons are triggered to respond to different types of behavior actions according to the classification result of the human postures.

The embodiment constructs a man-machine-information-service digital twin virtual scene where an escalator carries passengers, and a digital twin virtual person is used to simulate risky behavior, to make up for a lack of data and solve a question of passenger risky behavior monitoring in practice. A three-dimensional visual interface of digital twin vividly and intuitively displays an operation state of the escalator apparatus and behavior information of the passengers, so as to implement early warning of potential risky behavior of the passengers, and implement automatic operation stop of the escalator apparatus at the first time of falling. The digital twin based method for monitoring behavior of a passenger on an escalator has the advantages of high real-time, high accuracy and high interactivity, and improves the degree of intelligence and digitization of operation and maintenance of the escalator.

What is described in the embodiments of the specification is merely an exemplification of forms in which the inventive concept can be implemented, and is for illustrative purposes only. The scope of protection of the present invention should not be construed as being limited to the particular forms set forth in the embodiments. The scope of protection of the present invention also extends to equivalent technical means that can occur to those of ordinary skill in the art according to the concept of the present invention.

What is claimed is:

1. A digital twin based method for monitoring behavior of a passenger on an escalator, comprising:
step 1: constructing a digital twin virtual scene of the escalator for carrying the passenger, comprising:
step (1.1) drawing a geometric model of the escalator and the passenger: drawing the geometric model by a three-dimensional modeling software, wherein the digital twin virtual scene determines a final realization effect of the digital twin scene and a degree of fidelity of the virtual scene based on the geometric model;
step (1.2) constructing the digital twin virtual scene: constructing a subject same with a real subject in reality for a complex step system in the geometric model, defining an attribute of a motion component, and defining a data interface of the motion component; and
step (1.3) driving the geometric model;
step 2: constructing a virtual person model in a physics engine, generating a virtual person model generating different actions corresponding to various types of risky behavior in the reality, making a virtual camera, and outputting different types of behavior of a virtual person, wherein the step 2 comprises:
step (2.1) obtaining behavior data of an actual person, and performing a posture decomposing process to obtain 18 key points;
step (2.2) designing action simulation behavior of the virtual person, reorienting a skeleton model of the virtual person in the physics engine, wherein the reorienting the skeleton model of the virtual person in the physics engine comprises: achieving simulation of the actual person by means of rotation and displacement in the skeleton model, matching a relation between skeleton points anew by means of matching set, and editing a space position of each key point of the virtual person, to simulate the behavior of the passenger in a real world; and
step (2.3) adding the virtual camera in the physics engine, binding visual angle selection of the camera with the virtual person, setting a photographing parameter of the virtual camera, selecting an output save path, and using a video image of the virtual person as input of behavior posture recognition and classification;
step 3, using a visual geometry group 19 (VGG19) pre-training network by a human posture recognition method for monitoring behavior of a passenger, extracting a feature map as input and entering two branches of part point affinity fields (PAFs) and point confidence maps (PCM), and using the PAFs to express a trend of a pixel point on a posture, wherein the step 3 comprises:
step (3.1) obtaining the feature map from an original image by the VGG19 pre-training network;
step (3.2) outputting the obtained feature map to a next layer, entering the two branches, and outputting one Loss in each stage, wherein the two branches comprises a branch PAFs and a branch PCM;
step (3.3) generating and computing a confidence map S by using an image of two-dimensional key points, wherein all confidence maps S*_{j,k}(p) are generated by k persons, X_{j,k} represents a jth key point of a kth person in the image, and a maximum value of the all confidence maps S*_{j,k}(p) is a finally obtained confidence map of key point parts of a plurality of persons; wherein a predicted value at p is:
$${S}_{j , k}^{*} ( p ) = exp ( - \frac{{‖ p - {X}_{j , k} ‖}_{2}^{2}}{{δ}^{2}} )$$
wherein exp is a natural constant e, & is a diffusion of a control peak, and ∥p−X_{j,k}∥₂² is a square of a vector modulus value from the point p to a position j of the kth person;
step (3.4) defining that X_{i,k} and X_{j,k} represent two key points, and the pixel point p step (3.4) defining that Xix and is on a limb, such that a value of L*_{c,k}(p) is a unit vector from i to j of the kth person, wherein a vector field of the point p is:
$${L}_{c , k}^{*} ( p ) = \{ \begin{matrix}\frac{( {X}_{j , k} - {X}_{i , k} )}{{‖ {X}_{j , k} - {X}_{i , k} ‖}_{2}} , & p ∈ {L}_{c , k}^{*} ( p ) \\ 0 , & others\end{matrix}$$
wherein ∥X_{j,k}−X_{i,k}∥₂ is a limb length from a position j to position i of the kth person;
step (3.5) obtaining an average affinity field of all the persons as:
$${L}_{c}^{*} ( p ) = \frac{1}{{n}_{c} ( p )} {L}_{c , k}^{*} ( p )$$
wherein n_{c}(p) represents a number of non-zero vectors at p in all the persons;
step (3.6) computing a score of a limb by means of the following formula in a multi-person scene, and searching for a situation with a maximum association confidence coefficient;
$$E = {\int }_{u = 0}^{u = 1} {L}_{c} ( p ( u ) ) \frac{{d}_{j 2} - {d}_{j 1}}{{‖ {d}_{j 2} - {d}_{j 1} ‖}_{2}} du$$
wherein E is the association confidence coefficient, ∥dⱼ₂−dⱼ₂∥₂ is a distance between body parts dⱼ₂, dⱼ₁, and p(u) interpolates positions of the body parts dⱼ₂, dⱼ₁:
p(u)=(1−u)dⱼ₁+dⱼ₂
wherein an integral value is approximated by means of sampling and equally spaced sums over u; and
step (3.7) changing a multi-person detection into a bipartite graph matching to obtain an optimal solution of connected points, obtaining all limb prediction results, and connecting all key points of a human body;
wherein the bipartite graph matching is a subset of edges selected in such a way that two edges share no node to find a matched maximum weight for a selected edge;
step 4, performing posture classification based on a support vector machine (SVM), using 1-V-1(one-versus-one) to classify a plurality of human postures, wherein designing one SVM classifier for every two classes, and k(k−1)/2 classifiers are needed in total; and
step 5: performing emergency stop control on the escalator under risky behavior.

2. The digital twin based method for monitoring behavior of a passenger on an escalator according to claim 1, wherein in the step (1.1), the escalator comprises a truss, a step system, a handrail belt system, a guide rail system, a handrail device, a safety protection device, an electrical control system, and a lubrication system;
wherein the truss is a support structure of the escalator, and is configured to mount and support various components of the escalator;
wherein the step system is a working part of the escalator, and is composed of step treads, a drive main machine, a step chain, a main drive shaft and a roller chain;
wherein the handrail belt system functions to provide a set of handrail belts synchronized with steps in movement, so as to achieve synchronization of a hand and a body when the passenger takes the elevator;
wherein the guide rail system is configured to support a load transmitted by a main wheel and an auxiliary wheel of the steps, to prevent the steps from running away;
wherein the handrail device is arranged on two sides of the escalator;
wherein the safety protection device is various protection devices set on the escalator for a potential safety hazard;
wherein the electrical control system is to implement drive control over an electric motor, and to perform safety monitoring and safety protection on operation of the escalator;
wherein the lubrication system is configured to lubricate machine parts of the escalator, reasonable lubrication reduces wear of moving components and prolongs the service life of the escalator;
wherein a human model is simplified to a virtual skeleton model with 18 key points having limited rotation displacement;
wherein the 18 key points are respectively a neck point, a nose point, a left eye point, a right eye point, a left ear point, a right ear point, a left shoulder point, a right shoulder point, a left elbow point, a right elbow point, a left wrist point, a right wrist point, a left hip bone point, a right hip bone point, a left knee point, a right knee point, a left ankle point, and a right ankle point, wherein, the middle of the left shoulder point and the right shoulder point is taken as the neck point in human posture recognition.

3. The digital twin based method for monitoring behavior of a passenger on an escalator according to claim 2, wherein in the step (1.2), a movement mode of the step treads in the step system is that any tread is taken as an initial tread, a movement path of the step treads of the escalator is constructed, a movement speed v of the treads is computed from a height and an elevator length, that is, an included angle θ, a constraint is set, the initial tread moves along the path, a movement path length l and an occupation width d of the initial tread in the path are computed, a number of the step treads is determined as l÷d=n , n is an integer, in response to determining that n is not an integer, the movement path length l or a step tread width is finely adjusted, the initial tread is taken as a parent node, a second tread is bound to the previous tread, a third tread is bound to the second tread, and so on, all the treads form a complete step tread along the movement path, and by controlling a speed of the initial tread, all the treads move along the movement path at the same speed;
wherein movement of the roller chain in the step system is the same as that of the step treads;
wherein the attribute of the motion component is operability of translation and rotation of the motion component in the physics engine; and
wherein the data interface of the motion component is that in the physics engine, start, stop and a speed of a movable component are controlled according to truthful data.

4. The digital twin based method for monitoring behavior of a passenger on an escalator according to claim 3, wherein in the step (1.3), a process of driving the geometric model comprises:
step (1.3.1) uploading operation data of the escalator from a control panel to a client by means of a communication bus, wherein the client is a digital twin monitoring platform, and establishing bidirectional communication by means of Socket (bidirectional communication between application processes on different hosts in a network);
step (1.3.2) after human posture information is detected from collected passenger behavior data by a video analysis server in step 3, transmitting a passenger behavior video and key point data of the human postures to the client; and
step (1.3.3) receiving warning and stop commands from the client by a Socket server, and sending a command by means of a computer, to control the escalator to stop operating.

5. The digital twin based method for monitoring behavior of a passenger on an escalator according to claim 1, wherein in the step (3.1), the VGG19 pre-training network is a convolutional neural network for object recognition, and each layer of the neural network will further extract more complex features by using output of the previous layer until the feature is too complex to be used to recognize an object, wherein each layer is regarded as an extractor of many local features, and the step (3.1) comprises:
step (3.1.1) defining that a VGG19 module comprises 16 convolutional layers and 3 fully-connected layers, and an input image is 224*224*3, activating the input image with a rectified linear unit (ReLU) after 64 convolution kernels of 3*3, such that the input image becomes 224*224*64, and performing MAX pooling, such that a pooling window is 2*2, a step size is 2, and a pooled image is 112*112*64; wherein
each convolutional layer in the convolutional neural network consists of several convolutional units, parameters of each convolutional unit are optimized by a backpropagation algorithm, a purpose of convolutional operation is to extract different input features, the first convolutional layer extracts some low-level feature edges, lines and corner levels, and more layers of networks iteratively extract more complex features from the low-level features;
in the fully-connected layer, each node is connected to all nodes in the previous layer, to synthesize the features extracted above, and because of a fully connected feature of the fully-connected layer, the fully-connected layer has the most parameters;
during image processing, an input image is provided, pixels in a small region of the input image are weight and averaged to become each corresponding pixel in the output image, a weight is defined by a function, and the function is called the convolution kernel;
the rectified linear unit (ReLU) is a function operating on a neuron of an artificial neural network, and is responsible for mapping input of the neuron to an output end and used for output of a hidden layer neuron;
MAX pooling is to take a point with a maximum value from a local acceptance domain, and a size of a MAX pooling convolution kernel is 2*2;
step (3.1.2) performing 128 convolutions of 3*3 and the ReLU, such that the feature becomes 112*112*128, and performing 2*2 MAX pooling, such that a size becomes 56*56*128;
step (3.1.3) performing 256 convolutions of 3*3 and the ReLU, such that the feature becomes 56*56*256, and performing 2*2 MAX pooling, such that the feature size becomes 28*28*256;
step (3.1.4) performing 512 convolutions of 3*3 and the ReLU, such that the feature becomes 28*28*512, and performing 2*2 MAX pooling, such that the feature size becomes 14*14*512;
step (3.1.5) performing 512 convolutions of 3*3 and the ReLU, such that the feature becomes 14*14*512, and performing 2*2 MAX pooling, such that the feature size becomes 7*7*512; and
step (3.1.6) by means of two layers of 1*1*4096 and one layer of 1*1*1000 of the fully-connected layers and the ReLU, finally outputting 1000 prediction results by means of Softmax, wherein
a Softmax normalized exponential function is an extension of a logic function, and compresses a U-dimensional vector z containing any real number into another U-dimensional real vector α(z), such that a range of each element is between (0,1), and a sum of all elements is 1.

6. The digital twin based method for monitoring behavior of a passenger on an escalator according to claim 5, wherein the step (3.2) comprises:
step (3.2.1) defining an iteration formula of the branch PAFs as follows:
S^{t}=ρ^{t}(F, L^{t-1}, S^{t-1}), t≥2
wherein ρ^{t} represents an iterative relation of a stage t, F is the feature map, L represents the part affinity field, S represents the two-dimensional confidence map, and t represents the total number of stages;
step (3.2.2) defining an iteration formula of the branch PCM as follows:
L^{t}=ϕ^{t}(F, L^{t-1}, S^{t-1}), t≥2
wherein ϕ^{t} represents the iterative relation of the stage t;
step (3.2.3) defining a loss function of the branch PAFs as follows:
$${f}_{S}^{t} = {\sum }_{j = 1}^{J} {\sum }_{P} W ( p ) {‖ {S}_{j}^{t} ( p ) - {S}_{j}^{*} ( p ) ‖}_{2}^{2}$$
wherein fₛ^{t} is the loss function of the branch PAFs, S*ⱼ(p) is a confidence map of a real key point position, W is a binary code, and when no mark is made at the image pixel position p, W(p) is 0, otherwise is 1; and ∥Sⱼ^{t}(p)−S*ⱼ(p)∥₂² is a square of a difference between a predicted value and a true value; and
step (3.2.4) defining a loss function of the branch PCM as follows:
$${f}_{L}^{t} = {\sum }_{c = 1}^{C} {\sum }_{P} W ( p ) {‖ {L}_{c}^{t} ( p ) - {L}_{c}^{*} ( p ) ‖}_{2}^{2}$$
wherein f_{L}^{t} is the loss function of the branch PAFs, L*_{c}(p) is a part affinity field of real key points, and ∥L_{c}^{t}(p)−L*_{c}(p)∥₂² is the square of the difference between the predicted value and the true value.

7. The digital twin based method for monitoring behavior of a passenger on an escalator according to claim 1, wherein the step 4 comprises:
step (4.1) performing data processing and normalization: training and testing data, to select a posture key point coordinate, and normalizing key point coordinate data in different types of posture data, wherein
normalization processing is to scale the key point coordinate data to [−1, 1];
step (4.2) selecting a radial basis function kernel as a kernel function, wherein definition of the radial basis kernel function is as follows:
$$K ( x , {x}^{′} ) = exp ( - \frac{{‖ x - {x}^{′} ‖}_{2}^{2}}{2 {σ}^{2}} )$$
wherein x and x′ are two trained samples, ∥x−x∥₂² is a squared Euclidean distance between vectors, and σ is a free parameter;
step (4.3) selecting reasonable training parameters c and g, wherein c represents an importance degree of the model to discrete group data, and g is γ=½² in the kernel function;
step (4.4) using the parameters of step (4.3) to train a posture classification model; and
step (4.5) verifying accuracy of classification, and verifying an accuracy rate of classification of a test set according to the trained model.

8. The digital twin based method for monitoring behavior of a passenger on an escalator according to claim 1, wherein the step 5 comprises:
step (5.1) after human posture information is detected by a video analysis server, transmitting a passenger behavior video and key point data of the human postures to the client to recognize the behavior of the passenger;
step (5.2) classifying recognition results of the behavior of the passenger by the client, to correspondingly trigger a state machine in the virtual scene, wherein a posture recognition result triggers the virtual person behavior to be converted into a corresponding posture, wherein
the state machine is a tool in the physics engine that makes one action of the virtual person transition to another action; and
step (5.3) sending out warning and stop commands by the client according to the classified recognition results of the behavior of the passenger, and sending the warning and stop commands to a control mainboard of the elevator by means of the communication bus to control the escalator to stop operating.
